(19) United States
(12) Patent Application Publication
(10) Pub. No.: US 2026/0107616 A1
(43) Pub. Date: Apr. 16, 2026

(54) ELECTRONIC DEVICE

(71) Applicant: INNOLUX CORPORATION, Miao-Li County (TW)

(72) Inventors: Tun-Ting YANG, Miao-Li County (TW); Chia-Chi KUO, Miao-Li County (TW); Yi-An CHEN, Miao-Li County (TW); Kuan-Hung KUO, Miao-Li County (TW)

(21) Appl. No.: 19/336,035

(22) Filed: Sep. 22, 2025

(30) Foreign Application Priority Data
Oct. 11, 2024 (CN) 202411415847.6

(51) Int. Cl. H10H 29/852; H01L 25/075; H10H 29/37; H10H 29/85; H10H 29/851

(52) U.S. Cl. CPC H10H 29/852; H10H 29/37; H10H 29/8512; H10H 29/8517; H10W 90/00

(57) ABSTRACT

An electronic device, which has a plurality of display areas and a transmissive area surrounding the display areas, includes a first substrate, multiple light-emitting units, multiple first optical units, a first encapsulating layer, and a second encapsulating layer. The light-emitting units are arranged on the first substrate and disposed in the display areas, respectively. The first optical units are disposed in the display areas, respectively, and located above the light-emitting units, respectively. The first encapsulating layer is arranged on the light-emitting units and located between the light-emitting units and the first optical units. The second encapsulating layer is disposed on the first optical units. The first encapsulating layer contacts the second encapsulating layer in the transmissive area, so that the first optical units are enclosed in a plurality of spaces formed by the first encapsulating layer and the second encapsulating layer.

### CROSS REFERENCE TO RELATED APPLICATIONS

This Non-provisional application claims priority under 35 U.S.C. § 119(a) on Patent Application No(s). 202411415847.6 filed in China on Oct. 11, 2024, the entire contents of which are hereby incorporated by reference.

### BACKGROUND

### Technology Field

The present disclosure relates to an electronic device and, in particular, to a display device.

### Description of Related Art

In general, the common display devices usually utilize the light mixing of different color lights to achieve the color display effect. For example, in an LED (light-emitting diode) display device, each pixel can be configured with three color LEDs, such as a red LED, a green LED, and a blue LED. However, this design has the problem that the efficiencies of the three color LEDs are different, and the yield of mass-transferring the three color LEDs is low.

In another design, the LEDs of the same color (e.g. blue LEDs) can be used in conjunction with light conversion materials to generate different color lights, thereby achieving the color display effect. However, some light conversion materials (e.g. the red light conversion material) are easily affected by environmental moisture and/or oxygen, resulting in poor product reliability. In addition, the light conversion material is disposed in a plurality of openings in a bank layer located above the light-emitting elements, and the bank layer is usually a layer structure laid in the whole display panel. This structure makes the electronic device become non-bendable, which is not conducive to the manufacture of a flexible display device with the light conversion materials.

### SUMMARY

This disclosure provides an electronic device that can protect the light conversion materials from being affected by environmental moisture and/or oxygen, and is suitable for using the light conversion materials to manufacture a flexible display device.

An electronic device, which has a plurality of display areas and a transmissive area surrounding the display areas, includes a first substrate, a plurality of light-emitting units, a plurality of first optical units, a first encapsulating layer, and a second encapsulating layer. The light-emitting units are arranged on the first substrate and disposed in the display areas, respectively. The first optical units are disposed in the display areas, respectively, and located above the light-emitting units, respectively. The first encapsulating layer is arranged on the light-emitting units and located between the light-emitting units and the first optical units. The second encapsulating layer is disposed on the first optical units. The first encapsulating layer contacts the second encapsulating layer in the transmissive area, so that the first optical units are enclosed in a plurality of spaces formed by the first encapsulating layer and the second encapsulating layer.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a top view of an electronic device according to an embodiment of this disclosure;

FIG. 1B is a partial sectional view of the electronic device along the sectional line AA′ of FIG. 1A;

FIG. 2 to FIG. 5 are partial sectional views of the electronic devices according to different embodiments along the sectional line AA′ of FIG. 1A;

FIG. 6A is a top view of an electronic device according to another embodiment of this disclosure;

FIG. 6B is a partial sectional view of the electronic device along the sectional line BB′ of FIG. 6A;

FIG. 7 is a partial sectional view of the electronic device according to another embodiment along the sectional line BB′ of FIG. 6A;

FIG. 8A is a top view of an electronic device according to another embodiment of this disclosure;

FIG. 8B is a partial sectional view of the electronic device along the sectional line CC′ of FIG. 8A; and FIG. 9 is a partial sectional view of the electronic device according to another embodiment along the sectional line CC′ of FIG. 8A.

### DETAILED DESCRIPTION OF THE DISCLOSURE

The present disclosure will be apparent from the following detailed description, which proceeds with reference to the accompanying drawings, wherein the same references relate to the same elements.

It should be understood that the following description provides different embodiments for implementing different aspects of some embodiments of the present disclosure. The specific components and arrangements described below are used to briefly and clearly describe some embodiments of the present disclosure. These embodiments are for illustrations and are not intended to limit the scope of the present disclosure. In addition, reference numbers or labels may be repeatedly used in different embodiments. These repetitions are for the purpose of simply and clearly describing some embodiments of the present disclosure, and do not represent any correlation between the different embodiments and/or structures discussed. Furthermore, when it is mentioned that a certain element is on or above another element, the certain element may directly contact another element, or one or more other elements may be provided between the two elements, so that the certain element may not directly contact another element.

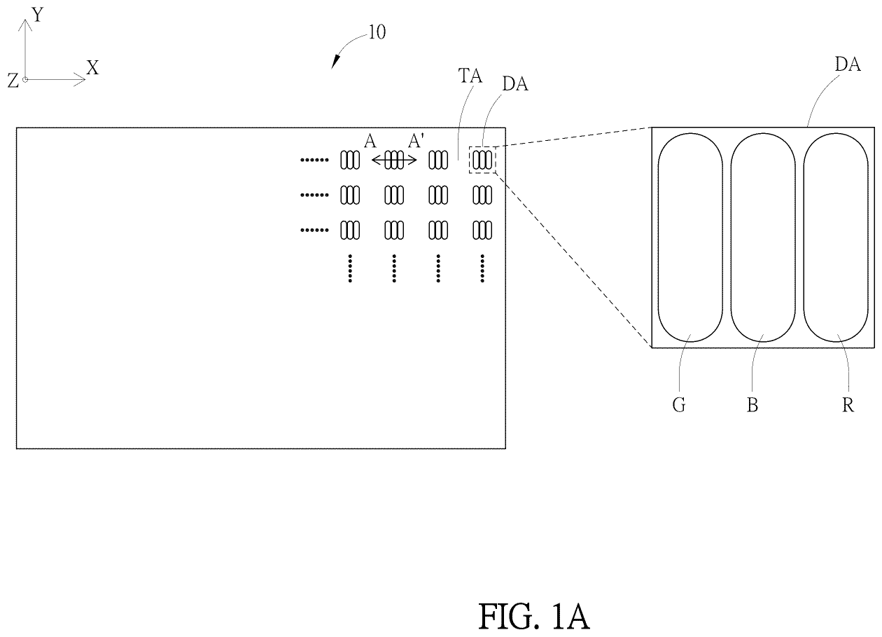

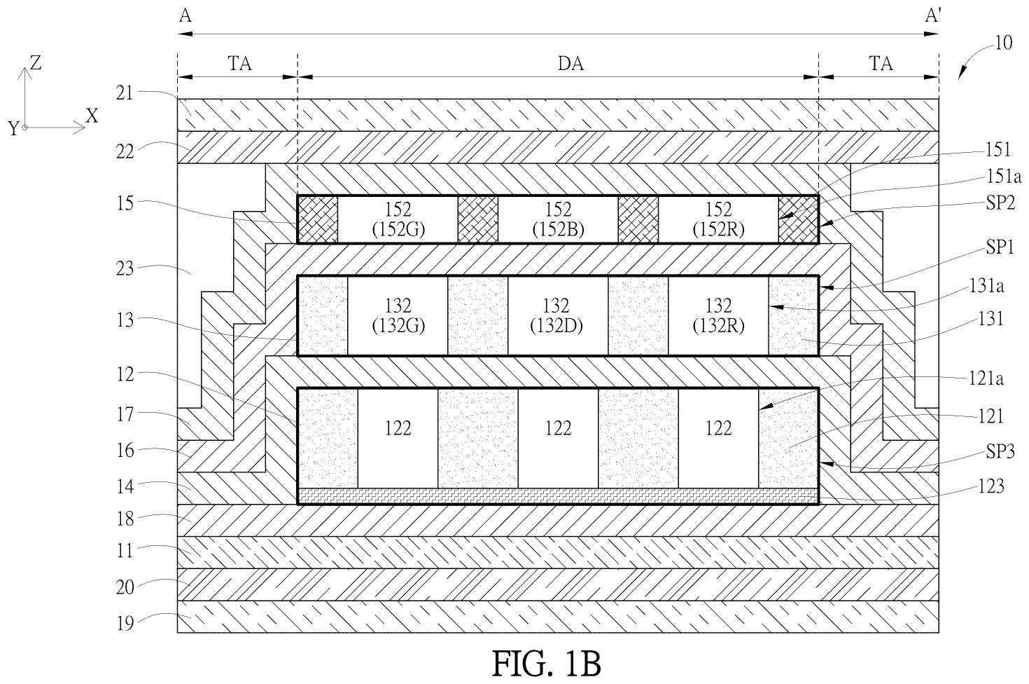

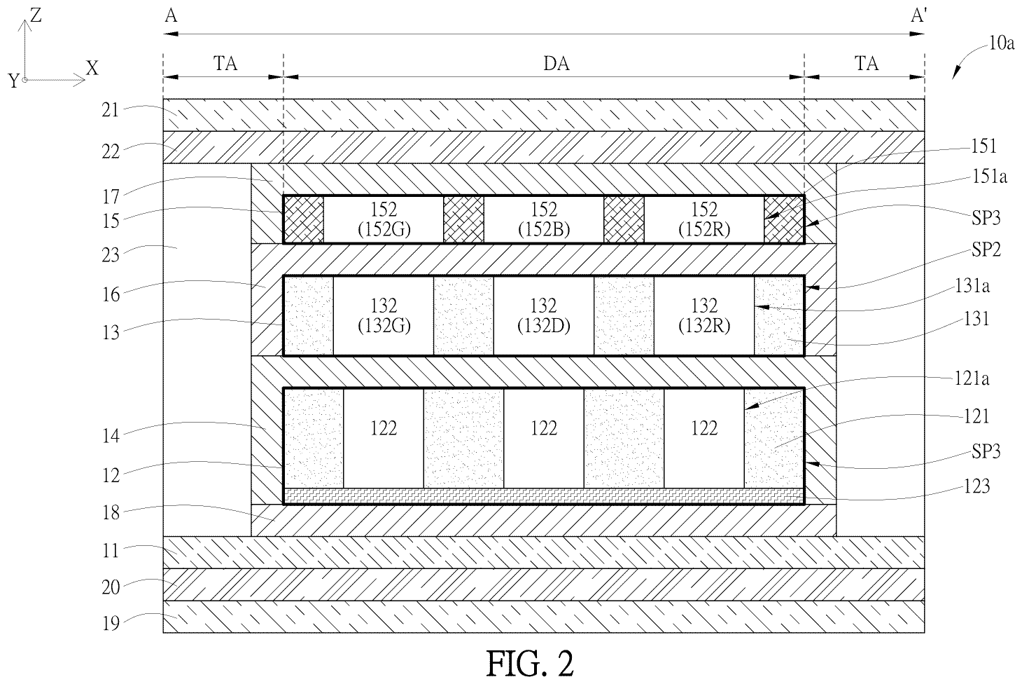

FIG. 1A is a top view of an electronic device 10 according to an embodiment of this disclosure, and FIG. 1B is a partial sectional view of the electronic device 10 along the sectional line AA′ of FIG. 1A.

To be noted, the features of several different embodiments may be replaced, reorganized, or mixed to implement any of other embodiments without departing from the spirit of the present disclosure.

As shown in FIG. 1A, the electronic device 10 of this embodiment may be, for example but not limited to, a display device having a plurality of display areas DA and a transmissive area TA surrounding the multiple display areas DA. In this case, each display area DA can define, for example, a pixel area, and each pixel area (each display area DA) may include multiple sub-pixel areas. In this embodiment, each display area DA may include three sub-pixel areas, such as a red sub-pixel area R, a green sub-pixel area G, and a blue sub-pixel area B, for emitting the red light, green light, and blue light respectively, thereby achieving the purpose of color display. To be noted, this disclosure is not limited thereto. As shown in FIG. 1A, in this embodiment, a plurality of display areas DA are arranged in a matrix manner, and the transmissive area TA surrounds the plurality of display areas DA. For example, the plurality of display areas DA may be arranged in a matrix manner on a plane defined by a first direction X and a second direction Y, wherein the first direction X is defined as a direction parallel to one of the long side and the short side of the electronic device 10, the second direction Y is defined as a direction parallel to the other one of the long side and the short side of the electronic device 10, and the second direction Y is perpendicular to the first direction X. In this embodiment, the transmissive area TA may include at least one transmissive region, so that the electronic device 10 can form a transmissive display device. For example, the entire transmissive area TA is a transmissive region, or only a portion of the transmissive area TA is a transmissive region.

Referring to FIGS. 1A and 1B, in this embodiment, the electronic device 10 includes a first substrate 11, a plurality of light-emitting units 12, a plurality of first optical units 13, a first encapsulating layer 14, a plurality of first color filter units 15, a second encapsulating layer 16, and a third encapsulating layer 17. To be noted, FIG. 1A is a top view of the electronic device 10, which shows that the electronic device 10 includes a plurality of display areas DA. FIG. 1B shows a sectional view of a display area DA and a transmissive area TA adjacent thereto of the electronic device 10, i.e., a sectional view along the section line AA′ as shown in FIG. 1A. Therefore, a display area DA shown in FIG. 1B includes a first substrate 11, a light-emitting unit 12, a first optical unit 13, a first encapsulating layer 14, a first color filter unit 15, a second encapsulating layer 16, and a third encapsulating layer 17.

The detailed structure within the range of a display area DA and a transmissive area TA adjacent thereto will be described hereinafter with reference to FIG. 1B. FIG. 1B shows a cross section defined by a first direction X and a third direction Z (e.g. a normal direction of a display surface of the electronic device 10), and the third direction Z is perpendicular to the first direction X and the second direction Y. The display area DA can be defined as the area of the orthographic projection of the first color filter unit 15 on the first substrate, and the light-emitting unit 12 and the first optical unit 13 are disposed in the display area DA. The transmissive area TA can be defined as the area outside the orthographic projection of the first color filter unit 15 on the first substrate.

As shown in FIG. 1B, one light-emitting unit 12 is disposed in one display area DA on the first substrate 11. Each light-emitting unit 12 includes a first bank layer 121 and at least one light-emitting element 122. One first optical unit 13 is located in the display area DA and disposed on the light-emitting unit 12. Each first optical unit 13 includes a second bank layer 131 and at least one first light conversion element 132, which is relatively located above the light-emitting element 122. One first color filter unit 15 is located in the display area DA and disposed on the first optical unit 13. Each first color filter unit 15 includes a first light-shielding layer 151 and at least one first color filter element 152, which is relatively located above the first light conversion element 132. The first encapsulating layer 14 is disposed on the light-emitting unit 12 and is located between the light-emitting unit 12 and the first optical unit 13. The second encapsulating layer 16 is disposed on the first optical unit 13 and is located between the first optical unit 13 and the first color filter unit 15. The third encapsulating layer 17 is disposed on the first color filter unit 15. The first encapsulating layer 14 contacts the second encapsulating layer 16 in the transmissive area TA, so that the first optical unit 13 is enclosed in the space SP1 formed by the first encapsulating layer 14 and the second encapsulating layer 16. The second encapsulating layer 16 contacts the third encapsulating layer 17 in the transmissive area TA, so that the first color filter unit 15 is enclosed in the space SP2 formed by the second encapsulating layer 16 and the third encapsulating layer 17. In this embodiment, based on the product requirements, each light-emitting unit 12 may include one or more light-emitting elements 122, each first optical unit 13 may include one or more first light conversion elements 132, and each first color filter unit 15 may include one or more first color filter elements 152. In this case, one light-emitting element 122 is disposed corresponding to one first light conversion element 132, and one first light conversion element 132 is disposed corresponding to one first color filter element 152. In other words, one light-emitting element 122 is located in the orthographic projection of a corresponding first light conversion element 132, and one first light conversion element 132 is located in the orthographic projection of a corresponding first color filter element 152.

In addition, the electronic device 10 may further include a fourth encapsulating layer 18, which is disposed between the first substrate 11 and the first encapsulating layer 14. The fourth encapsulating layer 18 contacts the first encapsulating layer 14 in the transmissive area TA, so that the light-emitting unit 12 is enclosed in the space SP3 formed by the first encapsulating layer 14 and the fourth encapsulating layer 18.

Moreover, the electronic device 10 may further include a first supporting layer 19 disposed at one side of the first substrate 11 away from the light-emitting unit 12. As shown in FIG. 1B, the first supporting layer 19 can be attached to the bottom of the first substrate 11 through a first adhesive layer 20. Similarly, the electronic device 10 may further include a second supporting layer 21 disposed at one side of the third encapsulating layer 17 away from the first color filter unit 15. As shown in FIG. 1B, the second supporting layer 21 may be attached to the top of the third encapsulating layer 17 through a second adhesive layer 22.

As mentioned above, in order to form a transmissive region in the transmissive area TA, a first light-transmitting material layer 23 may be formed between the third encapsulating layer 17 and the second supporting layer 21 (and/or the second adhesive layer 22) within the range of the transmissive area TA to increase the light transmittance of the transmissive area TA. For example, a photometer or a spectrometer can be used to measure the intensity S1 (in nit) of light after it passes through the electronic device 10. In an experimental example, a light source is set at one side of the electronic device 10 (e.g. the bottom side of the first supporting layer 19), and a photometer is set at the other side (e.g. the top side of the second supporting layer 21). The photometer is used to measure the intensity S1 of the light emitted from the light source and passing through the electronic device 10 (e.g. the transmissive area TA). In addition, the photometer is used to directly receive the light emitted from the light source (without passing through the electronic device 10) to obtain the reference light intensity S2. The ratio of the intensity S1 to the intensity S2 (S1/S2) can be calculated to obtain the light transmittance of the electronic device 10. Generally, the refractive index of each film or layer in the electronic device 10 (e.g. the transmissive area TA) will affect the light transmittance thereof. That is, the refractive index matching of the multiple layers can affect the light transmittance of the overall stacked structure. Therefore, designing the refractive indexes of the multiple layers to be similar can achieve a better light transmittance of the product.

The structure, material and other characteristics of each component will be describe hereinafter. In this embodiment, the first substrate 11 may be a flexible substrate, which may include, for example but not limited to, glass, quartz, sapphire, ceramic, polyimide (PI), any of other suitable materials, or any combination of the above materials. The coefficient of thermal expansion (CTE) thereof may be, for example, between 0 and 50 ppm/K (0<CTE<50 ppm/K), the maximum tensile strength (UTS) may be, for example, between 100 MPa and 1000 MPa (1000 MPa>UTS>100 MPa), and the elongation thereof may be, for example, between 7% and 100% (100%>elongation>7%). This disclosure is not limited thereto. Therefore, the electronic device 10 of this embodiment may be a flexible display device. In addition, the first substrate 11 can be a substrate including a circuit layer (not shown) electrically connected to the light-emitting unit 12. The circuit layer includes, for example, different passive components and/or active components. In addition, the first substrate 11 can be a driving substrate that drives the light-emitting unit 12 to emit light. The first substrate 11 can be, for example but not limited to, a CMOS substrate, a LCOS substrate, a TFT substrate, or other circuit substrates with working circuits.

In the light-emitting unit 12, as shown in FIG. 1B, the first bank layer 121 includes at least one first opening 121a configured to accommodate the light-emitting element 121a. In this embodiment, the first bank layer 121 includes, for example, three first openings 121a, and the light-emitting unit 12 includes three light-emitting elements 122 (e.g. three blue-light LEDs), which are accommodated in the three first openings 121a, respectively. In addition, a circuit layer 123 can be provided below and electrically connected to the light-emitting element 122, so that the light-emitting element 122 can be controlled and driven to emit light through the circuit layer 123. In this case, the circuit layer 123 can, for example, include active elements (e.g. thin-film transistors), passive elements (e.g. capacitors, bonding pads), multiple metal layers, and insulating layers between the multiple metal layers to drive the light-emitting element 122. In addition, the multiple circuit layers 123 can be electrically connected to each other. It should be noted that the circuit pattern of the circuit layer 123 is mainly arranged in the display area DA, and it may be partially arranged or totally not arranged in the transmissive area TA. In addition, the circuit layer 123 may be partially arranged within the range of each light-emitting unit 12. For example, the circuit pattern of the circuit layer 123 may be arranged below the first bank layer 121 and the light-emitting element 122. The above description is for example and is not intended to limit the scope of the present disclosure.

In the first optical unit 13, the second bank layer 131 includes at least one second opening 131a for accommodating the first light conversion element 132. In this embodiment, the second bank layer 131 may, for example, include three second openings 131a, and the first optical unit 13 may include three first light conversion elements 132, which are accommodated in the three second openings 131a, respectively. In this case, the first light conversion element 132, for example, includes a red light conversion element 132R, a green light conversion element 132G, and a light diffusion element 132D, which are respectively disposed above the light-emitting elements 122. In addition, the first light conversion element 132 of this embodiment may include, for example, a phosphor for converting the light emitted from the light-emitting element 122 into red light, green light, blue light or other suitable color light. In some other embodiments, the first light conversion elements 132 (e.g. the red light conversion element 132R and the green light conversion element 132G) may, for example, include a quantum dot material. The quantum dot material may have, for example, a core-shell structure, and the core thereof may include, for example but not limited to, any of other suitable materials, or any combination of the above materials. In addition, the first light conversion element 132 (e.g. the light diffusion element 132D) may simply include, for example, a material without the wavelength conversion function to replace the material of the above-mentioned quantum dots (e.g. phosphor particles, or other quantum dot materials). In this case, the material used to replace the material of the quantum dots may include, for example but not limited to, a polymer, a glass base, or titanium dioxide (TiO₂).

In the first color filter unit 15, the first light-shielding layer 151 is disposed on the second bank layer 131 and includes at least one third opening 151a for accommodating the first color filter element 152. That is, the third opening 151a is disposed on the above-mentioned second opening 131a. In this embodiment, the first light-shielding layer 151 may include, for example, three third openings 151a, and the first color filter unit 15 may include three first color filter elements 152, which are respectively disposed in the three third openings 151a. In this case, the first color filter elements 152 include, for example, a red color filter element 152R, a blue color filter element 152B, and a green color filter element 152G. Specifically, the red color filter element 152R mainly allows the red light to pass through, the blue color filter element 152B mainly allows blue light to pass through, and the green color filter element 152G mainly allows green light to pass through. The three first color filter elements 152 can be respectively disposed in different third openings 151a, so that the red color filter element 152R is disposed on the red light conversion element 132R, the blue color filter element 152B is disposed on the light diffusion element 132D, and the green color filter element 152G is disposed on the green light conversion element 132G. In this way, lights of specific wavelength bands can pass through the first color filter element 152 to achieve better display quality and contrast. Therefore, in this embodiment, the light (e.g. blue light) emitted by the first light-emitting element 122 can pass through the red light conversion element 132R and the red color filter element 152R in sequence to emit red light, the light (e.g. blue light) emitted by the second light-emitting element 122 can pass through the light diffusion element 132D and the blue color filter element 152B in sequence to emit blue light, and the light (e.g. blue light) emitted by the third light-emitting element 122 can pass through the green light conversion element 132G and the green color filter element 152G in sequence to emit green light. In addition, the first light-shielding layer 151 can be, for example, a black matrix layer (BM), and the material of the first light-shielding layer 151 can be, for example but not limited to, black photoresist, black printing ink, black resin, organic resin, glass paste. In other embodiments, the first light-shielding layer 151 can be, for example, functioned as a pixel definition layer (PDL), and the present disclosure is not limited thereto. The above description is for an illustration and is not intended to limit the scope of the present disclosure.

As shown in FIG. 1B, the electronic device 10 can further include a first encapsulating layer 14, a second encapsulating layer 16, a third encapsulating layer 17, and a fourth encapsulating layer 18, which may contact each other to form a plurality of enclosed spaces for accommodating the light-emitting units 12, the first optical units 13, and the first color filter units 15. Specifically, the first encapsulating layer 14 contacts the second encapsulating layer 16 in the transmissive area TA so as to form a plurality of enclosed spaces SP1 in the display area DA for accommodating the first optical units 13. The second encapsulating layer 16 contacts the third encapsulating layer 17 in the transmissive area TA so as to form a plurality of enclosed spaces SP2 in the display area DA for accommodating the first color filter units 15. The fourth encapsulating layer 18 contacts the first encapsulating layer 14 in the transmissive area TA so as to form a plurality of enclosed spaces SP3 in the display area DA for accommodating the light-emitting units 12. In this embodiment, the materials of the first encapsulating layer 14, the second encapsulating layer 16, the third encapsulating layer 17 and the fourth encapsulating layer 18 can be selected from materials with low water vapor transmission rate (WVTR), such as, for example but not limited to, and each of the first encapsulating layer 14, the second encapsulating layer 16, the third encapsulating layer 17 and the fourth encapsulating layer 18 can be formed by a CVD process or an ALD process. The materials of the first encapsulating layer 14, the second encapsulating layer 16, the third encapsulating layer 17 and the fourth encapsulating layer 18 can be the same or different, and the present disclosure is not limited thereto. For example, the first encapsulating layer 14, the second encapsulating layer 16, the third encapsulating layer 17 and the fourth encapsulating layer 18 of the present embodiment may have the following characteristics: the WVTR thereof may be no greater than 1*10⁻⁵ g/day/m², the refractive index thereof may be between 1.32 and 1.75, and the haze degree thereof may be less than 0.5. To be noted, the above description is for an illustration and is not intended to limit the scope of the present disclosure. In this embodiment, the first encapsulating layer 14, the second encapsulating layer 16, the third encapsulating layer 17 and the fourth encapsulating layer 18, which have low WVTR, are provided for fully encapsulating the light-emitting units 12, the first optical units 13 and the first color filter units 15, and this design can prevent external moisture and/or oxygen from damaging the light-emitting units 12, the first optical units 13 and the first color filter units 15 in the enclosed spaces. In particular, the light conversion materials in the first optical units 13 can be protected, so that this disclosure is suitable for using the light conversion material to manufacture a flexible transparent display device.

The first supporting layer 19 and the second supporting layer 21 can provide supporting and protecting functions, and the materials thereof include, for example but not limited to, polycarbonate (PC), polyethylene terephthalate (PET), or the likes.

The materials of the first adhesive layer 20 and the second adhesive layer 22 may include optical clear adhesive (OCA), optical clear resin (OCR) or any of other suitable transparent adhesive materials, but the present disclosure is not limited thereto. The first adhesive layer 20 and the second adhesive layer 22 may, for example, have the following characteristics of: the WVTR thereof may be no greater than 30 g/day/m², the transmittance thereof may be greater than 95%, and the refractive index thereof may be between 1.32 and 1.75. To be noted, the above description is for an illustration and is not intended to limit the scope of the present disclosure.

The first light-transmitting material layer 23 may be formed of, for example, a transparent negative photoresist, and may have the following characteristics of: the transmittance thereof may be greater than 99%, and the refractive index thereof may be between 1.32 and 1.75. To be noted, the above description is for an illustration and is not intended to limit the scope of the present disclosure. The electronic device 10 of this embodiment can form a transparent display device based on the design of the first light-transmitting material layer 23.

In another embodiment, the first substrate 11, the fourth encapsulating layer 18, the first supporting layer 19 and the first adhesive layer 20 can be together replaced by a glass substrate (e.g. an ITO glass substrate), and the second supporting layer 21 can be replaced by another (glass) substrate, the material of which can be, for example, glass, polymer film, resin, or adhesive layer. This structure can be, for example, a non-flexible transparent display device.

In another embodiment, the second encapsulating layer 16 in the previous embodiment as shown in FIG. 1B may be omitted. Therefore, the first color filter units 15 may be directly disposed on the first optical units 13, respectively, and the first encapsulating layer 14 contacts the third encapsulating layer 17 in the transmissive area TA so as to form enclosed spaces (not shown) in the display area DA for accommodating the first optical units 13 and the first color filter units 15. To be noted, the above description is for an illustration and is not intended to limit the scope of the present disclosure.

The structures and configurations of the electronic devices according to different embodiments of the present disclosure will be described hereinafter with reference to the drawings. To be noted, the following embodiments are for illustrations and are not intended to limit the scope of the present disclosure.

FIG. 2 is a partial sectional view of an electronic device 10a according to another embodiment along the sectional line AA′ of FIG. 1A. The component configurations and connections of the electronic device 10a of this embodiment are mostly the same as those of the display device 10 of the previous embodiment. Unlike the previous embodiment, in the electronic device 10a of this embodiment, the first light-transmitting material layer 23 extends downward to the first substrate 11. This design can greatly increase the proportion of the first light-transmitting material layer 23 in the transmissive area TA, thereby effectively improving the overall light transmittance of the electronic device 10a.

In another embodiment, the first substrate 11, the fourth encapsulating layer 18, the first supporting layer 19 and the first adhesive layer 20 can be together replaced by a glass substrate (e.g. an ITO glass substrate), and the second supporting layer 21 can be replaced by another substrate, the material of which can be, for example, glass, polymer film, resin, or adhesive layer. This structure can be, for example, a non-flexible transparent display device.

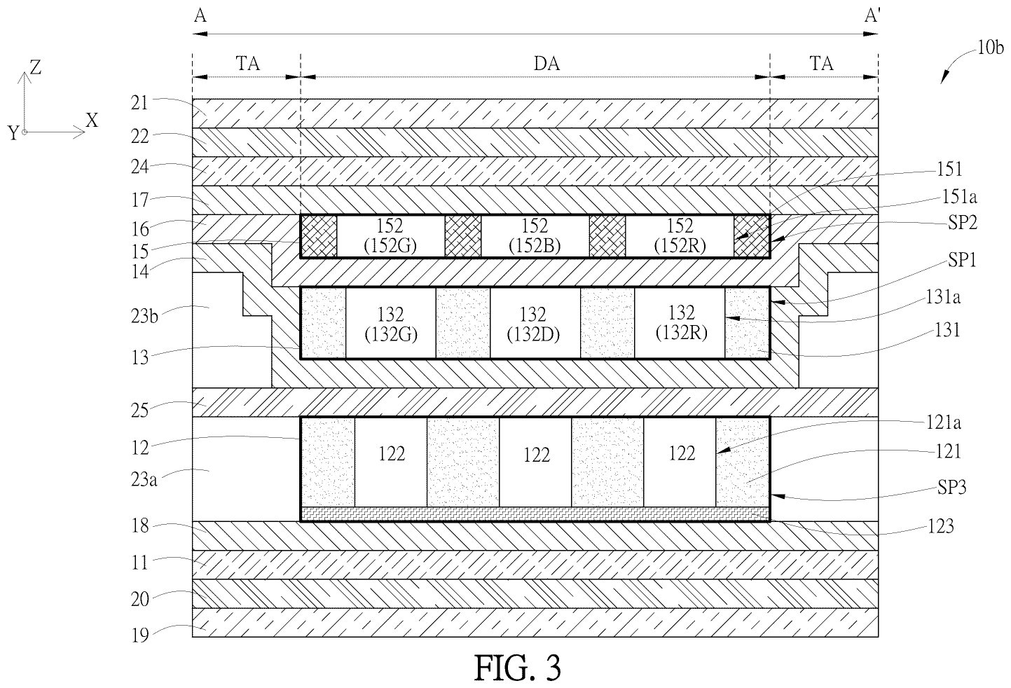

FIG. 3 is a partial sectional view of an electronic device 10b according to another embodiment along the sectional line AA′ of FIG. 1A. The component configurations and connections of the electronic device 10b of this embodiment are mostly the same as those of the display device 10 of the previous embodiment. Unlike the previous embodiment, the electronic device 10b of this embodiment further includes a second substrate 24 and a third adhesive layer 25. The second substrate 24 is disposed at one side of the first substrate 11 adjacent to the light-emitting units 12, the third encapsulating layer 17 contacts the second substrate 24, and the third adhesive layer 25 is disposed between the light-emitting units 12 and the first optical units 13. In this embodiment, as shown in FIG. 3, the second substrate 24 is disposed between the third encapsulating layer 17 and the second adhesive layer 22, and the third adhesive layer 25 is disposed between the light-emitting units 12 and the first encapsulating layer 14. The material and properties of the second substrate 24 may refer to those of the first substrate 11 in the aforementioned embodiment, and the material and properties of the third adhesive layer 25 may refer to those of the first adhesive layer 20 or the second adhesive layer 22 in the aforementioned embodiment, so the detailed descriptions thereof will be omitted here. In addition, the electronic device 10b of this embodiment includes two first light-transmitting material layers 23a and 23b. The first light-transmitting material layer 23a is arranged in the transmissive area TA around the light-emitting unit 12 and is located between the fourth encapsulating layer 18 and the third adhesive layer 25. The first light-transmitting material layer 23b is arranged in the transmissive area TA around the first optical unit 13 and is located between the first encapsulating layer 14 and the third adhesive layer 25. In this case, the structural design of the electronic device 10b is suitable for the manufacturing of dual-substrate product. For example, the light-emitting units 12 as well as other related components can be formed on the first substrate 11, and the first color filter units 15 and the first optical units 13 as well as other related components can be formed on the second substrate 24. Then, the two substrate structures are bonded using the third adhesive layer 25 to form the electronic device 10b. To be noted, the above description is for an illustration and is not intended to limit the scope of the present disclosure.

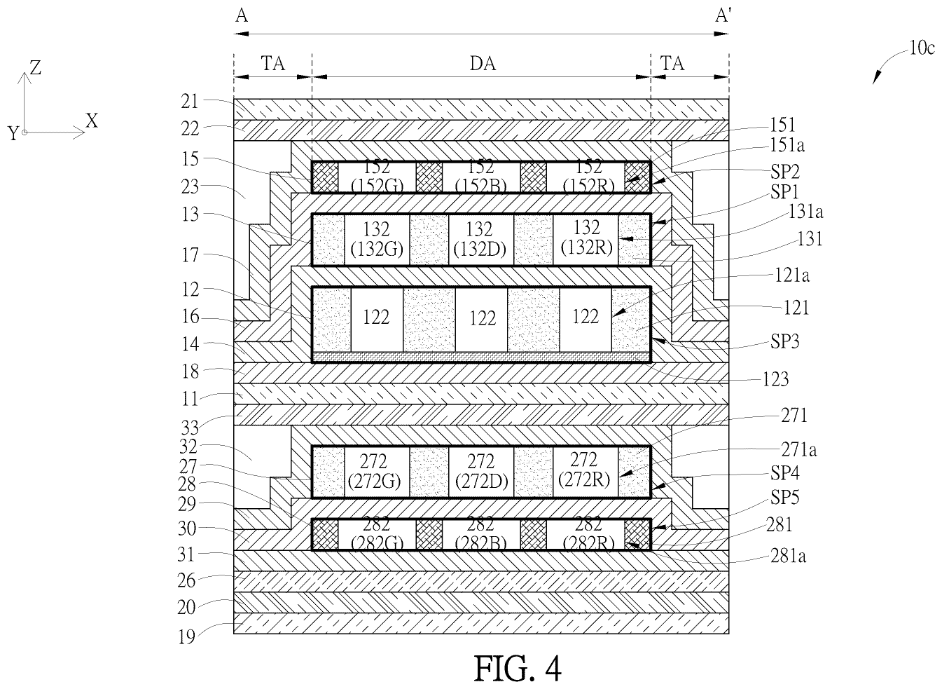

FIG. 4 is a partial sectional view of an electronic device 10c according to another embodiment along the sectional line AA′ of FIG. 1A. The component configurations and connections of the electronic device 10c of this embodiment are mostly the same as those of the display device 10 of the previous embodiment. Unlike the previous embodiment, the electronic device 10c of this embodiment further includes a third substrate 26, second optical units 27, second color filter units 28, a fifth encapsulating layer 29, a sixth encapsulating layer 30, a seventh encapsulating layer 31, a second light-transmitting material layer 32, and a fourth adhesive layer 33. FIG. 4 shows a sectional view of one display area DA and one adjacent transmissive area TA of the electronic device 10c, wherein the third substrate 26 is disposed at one side of the first substrate 11 away from the light-emitting unit 12, the second optical units 27 is disposed between the third substrate 26 and the first substrate 11, the second optical unit 27 is located in the display area DA and disposed under the light-emitting unit 12, the second color filter unit 28 is disposed between the third substrate 26 and the second optical unit 27, and is located in the display area DA and under the second optical unit 27, the second optical unit 27 is accommodated in the enclosed space SP4 formed by the fifth encapsulating layer 29 and the sixth encapsulating layer 30, and the second color filter unit 28 is accommodated in the enclosed space SP5 formed by the sixth encapsulating layer 30 and the seventh encapsulating layer 31. As shown in FIG. 4, the second optical unit 27 includes a third bank layer 271 and at least one second light conversion element 272. The third bank layer 271 may include, for example, three fourth openings 271a. Accordingly, the second optical unit 27 may include three second light conversion elements 272 respectively disposed in the three fourth openings 271a. In this case, the second light conversion elements 272 may include, for example, a red light conversion element 272R, a green light conversion element 272G, and a light diffusion element 272D, which are respectively disposed below the light-emitting elements 122. In addition, the second color filter unit 28 may include a second light-shielding layer 281 and at least one second color filter element 282. The second light-shielding layer 281 may include, for example, three fifth openings 281a. Accordingly, the second color filter unit 28 may include three second color filter elements 282 respectively disposed in the three fifth openings 281a. For example, the second color filter elements 282 include a red color filter element 282R, a blue color filter element 282B, and a green color filter element 282G, which are respectively arranged under the second light conversion elements 272. It should be noted that the material of the third substrate 26 can refer to the aforementioned first substrate 11, the material of the second optical unit 27 can refer to the aforementioned first optical unit 13, the material of the second color filter unit 28 can refer to the aforementioned first color filter unit 15, the materials of the fifth encapsulating layer 29, the sixth encapsulating layer 30, and the seventh encapsulating layer 31 can refer to the aforementioned first encapsulating layer 14, the second encapsulating layer 16, and the third encapsulating layer 17, the material of the second light-transmitting material layer 32 can refer to the aforementioned first light-transmitting material layer 23, and the material of the fourth adhesive layer 33 can refer to the aforementioned first adhesive layer 20, so the detailed descriptions thereof will be omitted here. As shown in FIG. 4, the electronic device 10c of this embodiment is, for example, a double-sided transparent display device. The first substrate 11 is configured with the light-emitting unit 12, the first optical unit 13 and the first color filter unit 15, and the third substrate 26 is configured with the second color filter unit 28 and the second optical unit 27. The light-emitting unit 12, the first optical unit 13 and the first color filter unit 15 may be encapsulated by the first encapsulating layer 14, the second encapsulating layer 16, the third encapsulating layer 17 and the fourth encapsulating layer 18. To be noted, the connection relationship and materials of the first encapsulating layer 14, the second encapsulating layer 16, the third encapsulating layer 17 and the fourth encapsulating layer 18 may refer to the electronic device 10 as shown in FIG. 1B, and the detailed description thereof will be omitted here. In addition, the second optical unit 27 and the second color filter unit 28 may be encapsulated by the fifth encapsulating layer 29, the sixth encapsulating layer 30 and the seventh encapsulating layer 31. Specifically, the fifth encapsulating layer 29 contacts the sixth encapsulating layer 30 in the transmissive area TA so as to form the enclosed space SP4 in the display area DA for accommodating the second optical unit 27. The sixth encapsulating layer 30 contacts the seventh encapsulating layer 31 in the transmissive area TA so as to form the enclosed space SP5 in the display area DA for accommodating the second color filter unit 28. The materials of the fifth encapsulating layer 29, the sixth encapsulating layer 30 and the seventh encapsulating layer 31 can refer to the materials of the first encapsulating layer 14, the second encapsulating layer 16 and the third encapsulating layer 17, and the detailed description thereof will be omitted here. Accordingly, the light conversion materials in the first optical unit 13 and the second optical unit 27 can be prevented from being damaged by ambient moisture and oxygen.

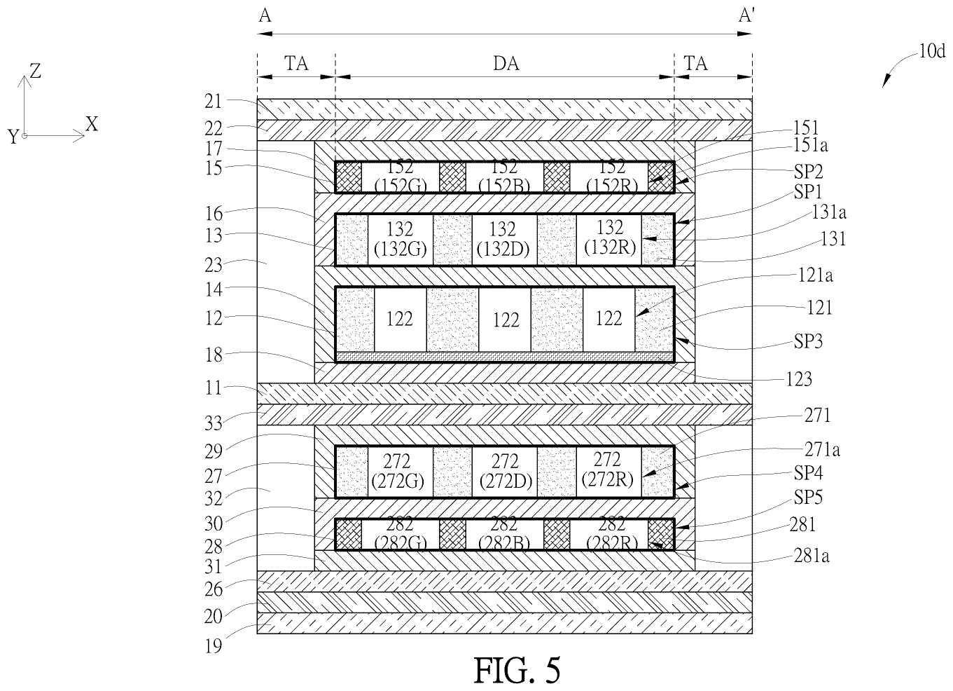

FIG. 5 is a partial sectional view of an electronic device 10d according to another embodiment along the sectional line AA′ of FIG. 1A. The component configurations and connections of the electronic device 10d of this embodiment are mostly the same as those of the display device 10c of the previous embodiment. Unlike the previous embodiment, in the electronic device 10d of this embodiment, the first light-transmitting material layer 23 extends downward to the first substrate 11, and the second light-transmitting material layer 32 extends downward to the third substrate 26. This design can greatly increase the proportion of the first light-transmitting material layer 23 and the second light-transmitting material layer 32 in the transmissive area TA, thereby effectively improving the overall light transmittance of the electronic device 10d.

In another embodiment, the first substrate 11 and the fourth encapsulating layer 18 can be together replaced by a glass substrate (e.g. an ITO glass substrate), and the second supporting layer 21 can be replaced by another substrate, the material of which can be, for example, glass, polymer film, resin, or adhesive layer. In addition, the first supporting layer 19, the first adhesive layer 20 and the third substrate 26 can be replaced by another glass substrate and an additional adhesive layer. This structure can be, for example, a non-flexible double-sided transparent display device.

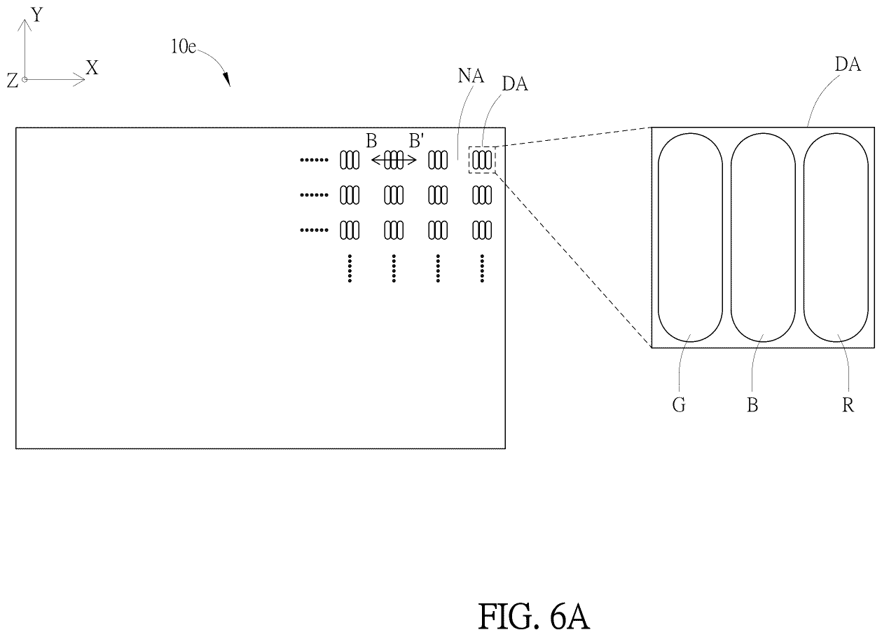

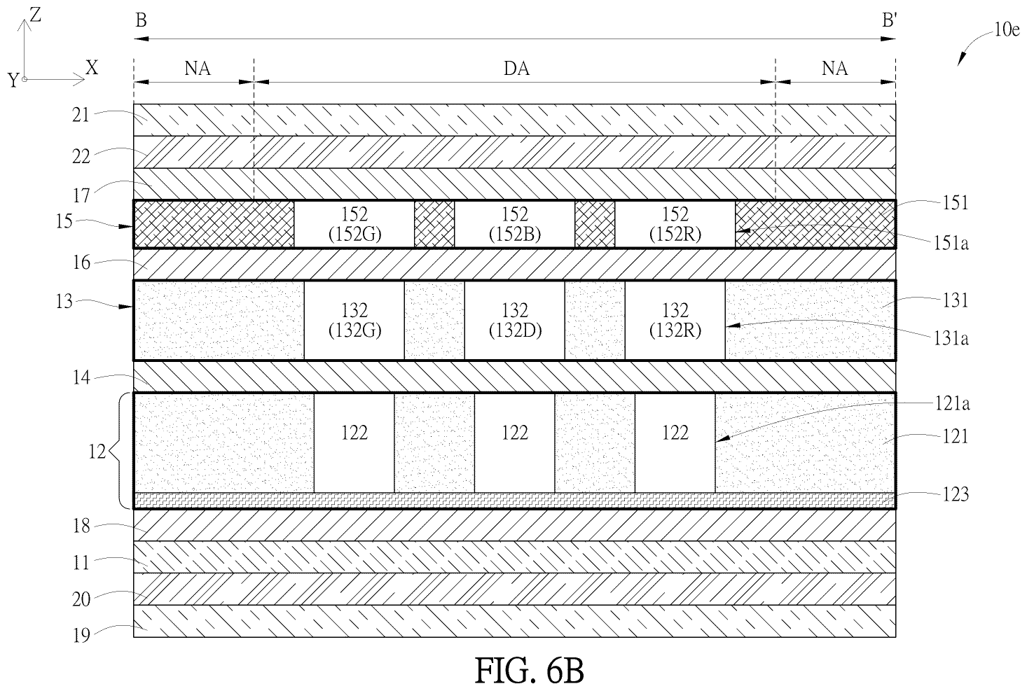

FIG. 6A is a top view of an electronic device 10e according to another embodiment of this disclosure, and FIG. 6B is a partial sectional view of the electronic device 10e along the sectional line BB′ of FIG. 6A.

As shown in FIG. 6A, the electronic device 10e of the present embodiment may be, for example but not limited to, a display device having a plurality of display areas DA and a non-display area NA surrounding the plurality of display areas DA. The detailed description thereof may refer to the electronic device 10 as shown in FIG. 1A and will be omitted here. It should be noted that FIG. 6A is a top view of the electronic device 10e, which shows that the electronic device 10e includes multiple display areas DA, and FIG. 6B shows a sectional view of one display area DA and the adjacent non-display area NA of the electronic device 10e. That is, FIG. 6B is a sectional view along the sectional line BB′ shown in FIG. 6A. Herein, FIG. 6B mainly shows the detailed structure of one display area DA.

As shown in FIG. 6B, the component configurations and connections of the electronic device 10e of this embodiment are mostly the same as those of the display device 10 of the previous embodiment (as shown in FIG. 1B). Unlike the previous embodiment, the electronic device 10e of this embodiment includes a non-display area NA instead of the transmissive area TA in the electronic device 10. In the electronic device 10e of this embodiment, the first bank layer 121 and the circuit layer 123 of the light-emitting unit 12, the second bank layer 131 of the first optical unit 13, and the first light-shielding layer 151 of the first color filter unit 15 all extend into the non-display area NA, and the first light-transmitting material layer 23 is not configured in the electronic device 10e. Therefore, the electronic device 10e can be, for example, a non-transparent flexible display device.

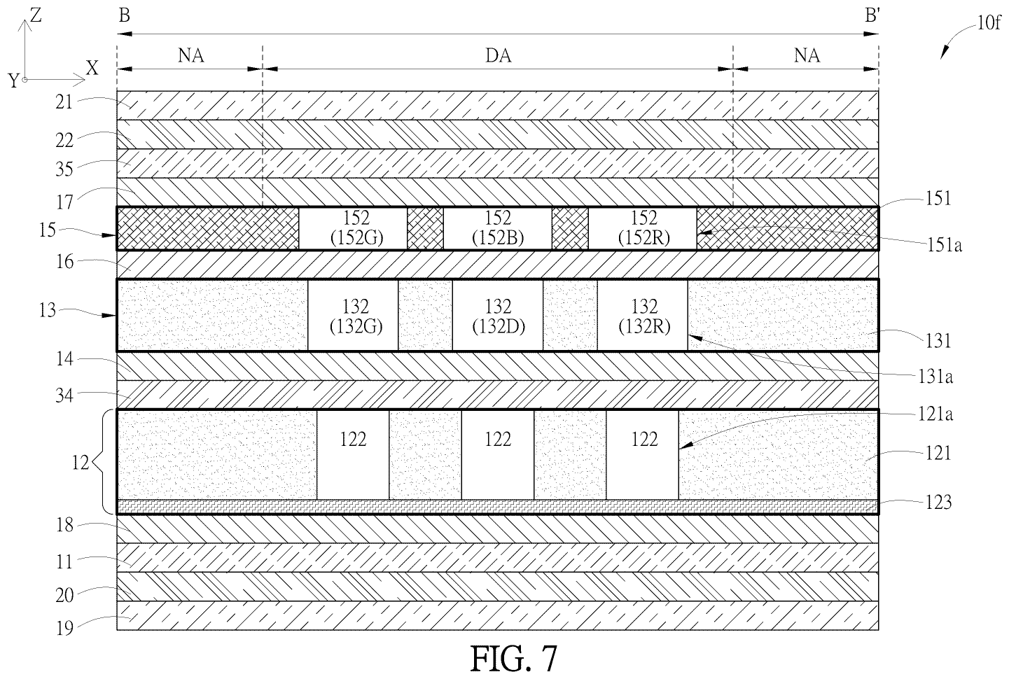

FIG. 7 is a partial sectional view of an electronic device 10f according to another embodiment along the sectional line BB′ of FIG. 6A. The component configurations and connections of the electronic device 10f of this embodiment are mostly the same as those of the display device 10e of the previous embodiment. Unlike the previous embodiment, in the electronic device 10f of this embodiment, a fifth adhesive layer 34 is further provided between the light-emitting unit 12 and the first encapsulating layer 14, and a fourth substrate 35 is further provided between the third encapsulating layer 17 and the second adhesive layer 22. The material of the fifth adhesive layer 34 can refer to the aforementioned first adhesive layer 20, and the material of the fourth substrate 35 can refer to the aforementioned first substrate 11, so the detailed descriptions thereof will be omitted here. In this embodiment, the light-emitting unit 12 may be disposed on the first substrate 11, and the first optical unit 13 and the first color filter unit 15 may be disposed on the fourth substrate 35. Then, the two substrates may be bonded together by using the fifth adhesive layer 34 to manufacture the electronic device 10f.

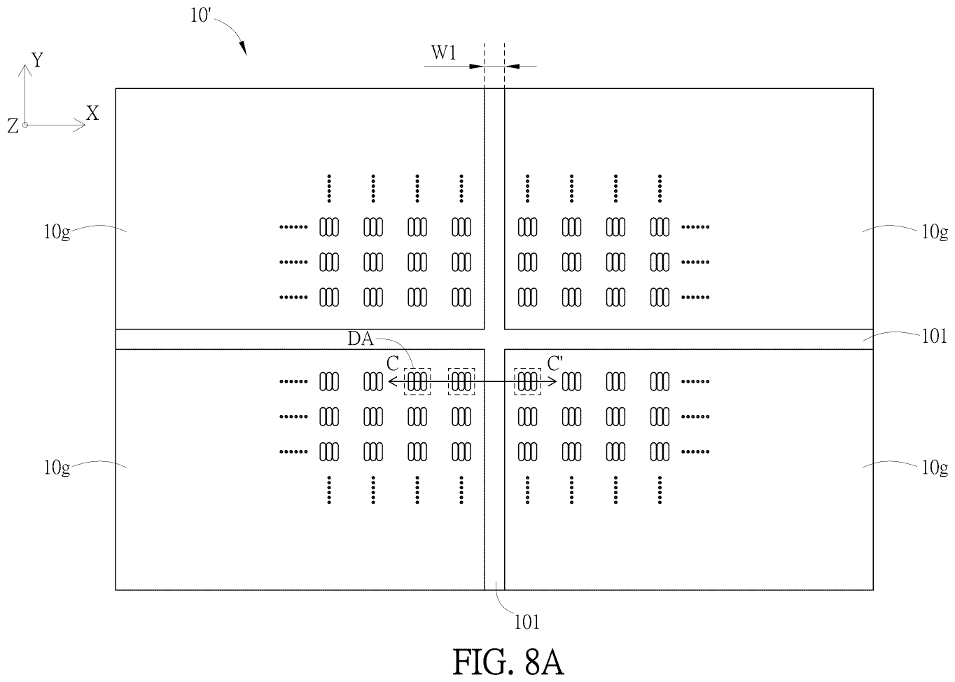

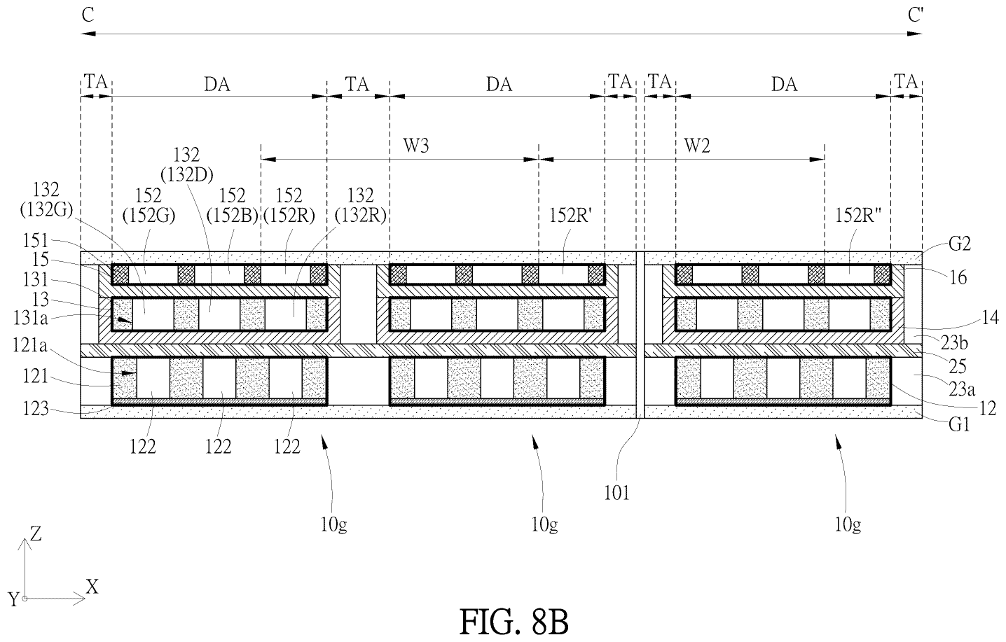

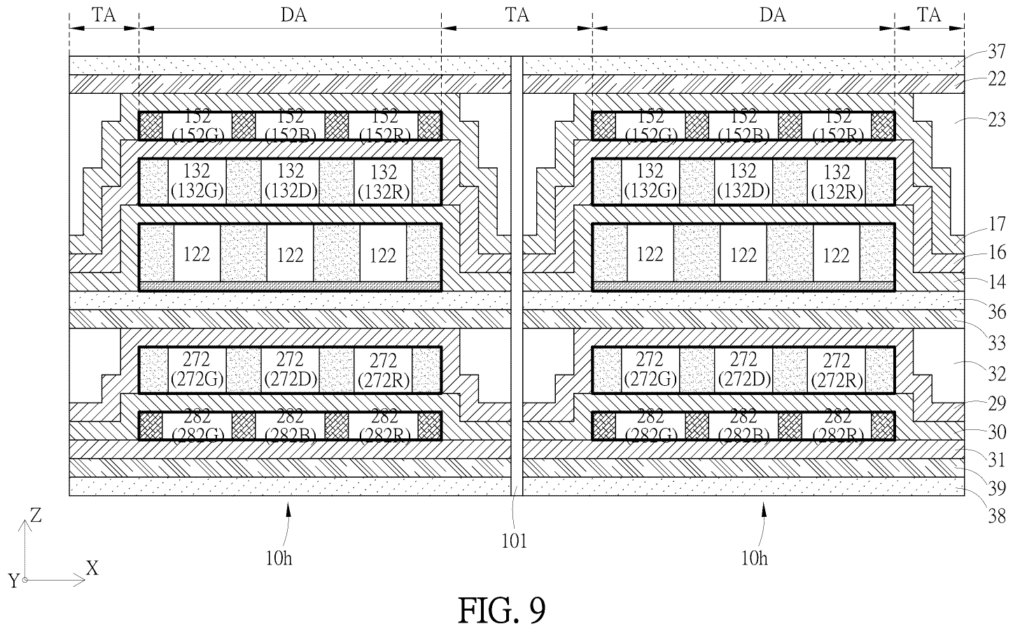

FIG. 8A is a top view of an electronic device 10′ according to another embodiment of this disclosure, and FIG. 8B is a partial sectional view of the electronic device 10′ along the sectional line CC′ of FIG. 8A. To be noted, FIG. 8A is a top view of the electronic device 10′, which shows that the electronic device 10′ includes multiple display panels 10g, and each display panel 10g includes multiple display areas DA. FIG. 8B shows a partial sectional view of two adjacent display panels 10g in the electronic device 10′, which includes, for example, two display areas DA of one display panel 10g and one display area DA of another adjacent display panel 10g. Specifically, FIG. 8B shows a sectional view along the section line CC′ as shown in FIG. 8A, so FIG. 8B mainly shows the detailed structure of the three display areas DA.

As shown in FIGS. 8A and 8B, the electronic device 10′ of this embodiment includes a plurality of display panels 10g and a tiling material 101 for tiling the display panels 10g. In this embodiment, each display panel 10g may be any of the aforementioned electronic devices 10˜10f or variations thereof. For example, the display panel 10g may be a flexible transparent display panel, such as the electronic device 10 as shown in FIG. 1B, the electronic device 10a as shown in FIG. 2, the electronic device 10b as shown in FIG. 3, the electronic device 10c as shown in FIG. 3, or the electronic device 10d as shown in FIG. 5, so that the electronic device 10′ formed by tiling the display panels 10g may form a flexible tiled transparent display device. In the present embodiment, the display panel 10g is a variation of the electronic device 10a as shown in FIG. 2, wherein the first substrate 11, the fourth encapsulating layer 18, the first supporting layer 19 and the first adhesive layer 20 can be replaced by a first glass substrate G1, the third encapsulating layer 17, the second supporting layer 21 and the second adhesive layer 22 can be replaced by a second glass substrate G2, and the two substrate structures are bonded together by an adhesive layer (e.g. the third adhesive layer 25 as shown in FIG. 3). In addition, the tiling material 101 has a width W1, and can include, for example, optical clear adhesive, optical clear resin, or any of other suitable transparent adhesive materials. The refractive index of the tiling material 101 can be, for example, between 1.32 and 1.75, so the electronic device 10′ can be, for example, a non-flexible large-sized transparent display device manufactured by tiling multiple display panels.

In addition, as shown in FIG. 8B, in order to reduce the influence of the tiling seam and improve the visual quality of the large-sized display device, the width of each tiling material 101 (tiling seam) can be adjusted according to the manufacturing processes, so that the pitch W2 between two adjacent first color filter elements (e.g. 152R′ and 152R″) that allow the same color light to pass through in two adjacent display panels 10g can be 30% more or less of the pitch W3 between two adjacent first color filter elements 152 (e.g. 152R and 152R′) that allow the same color light to pass through in one display panel 10g (i.e., W2=(1±30%)W3). The pitch “W2” can be obtained by measuring the width from the left side of the red color filter element 152R; to the left side of another red color filter element 152R″ as shown in FIG. 8B, and the pitch “W3” can be obtained by measuring the width from the left side of the red color filter element 152R to the left side of the red color filter element 152R′ as shown in FIG. 8B. It should be noted that the above description is for an illustration, and is not intended to limit the scope of the present disclosure.

FIG. 9 is a partial sectional view of the electronic device according to another embodiment along the sectional line CC′ of FIG. 8A.

The component configurations and connections of the electronic device of this embodiment as shown in FIG. 9 are mostly the same as those of the display device 10′ of the previous embodiment. Unlike the previous embodiment, the display panels 10h of this embodiment are, for example, flexible double-sided transparent display devices, which can be a variation of the aforementioned electronic device 10c (as shown in FIG. 4). A plurality of the display panels 10h can be tiled to from a flexible double-sided display device. In addition, the first substrate 11 and the fourth encapsulating layer 18 can be together replaced by a glass substrate 36 (e.g. an ITO glass substrate), the second supporting layer 21 can be replaced by another glass substrate 37, and the first supporting layer 19, the first adhesive layer 20 and the third substrate 26 can be replaced by another glass substrate 38 and a sixth adhesive layer 39. This structure can be, for example, a non-flexible double-sided tiled display device. The materials thereof can refer to the above embodiments, so the detailed descriptions thereof will be omitted here. In addition, the tiling material 101 may be a transparent material, so that the tiling material 101 can also be a part of the transmissive area TA of the electronic device.

To be noted, the display panel in the electronic device of this embodiment can be any of the aforementioned electronic devices 10˜10f, or a combination and/or variation thereof, and the present disclosure is not limited thereto. For example, the display panel of this embodiment can be the aforementioned electronic device 10d as shown in FIG. 5, and further in combination with the modifications of the display panel 10h described above. For example, the first light-transmitting material layer 23 can extend downward to the first substrate 11, and the second light-transmitting material layer 32 can extend downward to the third substrate 26. This design can greatly increase the proportion of the first light-transmitting material layer 23 and the second light-transmitting material layer 32 in the transmissive area TA, thereby effectively improving the overall light transmittance of the display panel 10h and the electronic device including the display panel 10h.

In summary, the electronic device of this embodiment has a plurality of display areas and a transmissive area surrounding the display areas, and includes a first substrate, a plurality of light-emitting units, a plurality of first optical units, a first encapsulating layer, and a second encapsulating layer. The light-emitting units are arranged on the first substrate and disposed in the display areas, respectively. The first optical units are disposed in the display areas, respectively, and located above the light-emitting units, respectively. The first encapsulating layer is arranged on the light-emitting units and located between the light-emitting units and the first optical units. The second encapsulating layer is disposed on the first optical units. The first encapsulating layer contacts the second encapsulating layer in the transmissive area, so that the first optical units are enclosed in a plurality of spaces formed by the first encapsulating layer and the second encapsulating layer. Based on the above-mentioned structural designs, the electronic device of this disclosure is configured with multiple encapsulating layers, such as the first encapsulating layer, the second encapsulating layer, the third encapsulating layer, the fourth encapsulating layer, etc., which are in contact with each other in the transmissive area so as to form multiple closed spaces in the display area, and the materials to be protected, such as light conversion materials, are arranged in these closed spaces. Because the encapsulating layers are made of the material with low WVTR (water vapor transmission rate), they can fully enclose the light-emitting units and the first optical units, thereby reducing the chance of external water vapor and/or oxygen contacting the light-emitting units and the first optical units, especially the light conversion materials in the first optical units, located in the enclosed spaces. In particular, this design is suitable for using the light conversion materials to manufacture flexible transparent display devices.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, which has a plurality of display areas and a transmissive area surrounding the display areas, comprising:
a first substrate;
a plurality of light-emitting units arranged on the first substrate, wherein the light-emitting units are disposed in the display areas, respectively;
a plurality of first optical units disposed in the display areas, respectively, and located above the light-emitting units, respectively;
a first encapsulating layer arranged on the light-emitting units and located between the light-emitting units and the first optical units; and
a second encapsulating layer disposed on the first optical units;
wherein, the first encapsulating layer contacts the second encapsulating layer in the transmissive area, so that the first optical units are enclosed in a plurality of spaces formed by the first encapsulating layer and the second encapsulating layer.

2. The electronic device of claim 1, further comprising:
a plurality of first color filter units disposed in the display areas, respectively, and located above the first optical units, respectively.

3. The electronic device of claim 2, further comprising:
a third encapsulating layer disposed on the first color filter units, wherein the second encapsulating layer contacts the third encapsulating layer in the transmissive area, so that the first color filter units are enclosed in a plurality of spaces formed by the second encapsulating layer and the third encapsulating layer; and
a fourth encapsulating layer disposed between the first substrate and the first encapsulating layer;
wherein, the fourth encapsulating layer contacts the first encapsulating layer in the transmissive area, so that the light-emitting units are enclosed in a plurality of spaces formed by the first encapsulating layer and the fourth encapsulating layer.

4. The electronic device of claim 2, wherein each of the first color filter units comprises a first light-shielding layer and a first color filter element, and the first light-shielding layer comprises a third opening for accommodating the first color filter element.

5. The electronic device of claim 1, wherein each of the light-emitting units comprises a first bank layer and a light-emitting element, and the first bank layer comprises a first opening for accommodating the light-emitting element.

6. The electronic device of claim 1, wherein each of the first optical units comprises a second bank layer and a first light conversion element, and the second bank layer comprises a second opening for accommodating the first light conversion element.

7. The electronic device of claim 1, further comprising:
a first supporting layer disposed at one side of the first substrate away from the light-emitting units.

8. The electronic device of claim 1, further comprising:
a second supporting layer disposed at one side of the third encapsulating layer away from the first optical units.

9. The electronic device of claim 8, further comprising:
a first light-transmitting material layer disposed in the transmissive area and located between the third encapsulating layer and the second supporting layer.

10. The electronic device of claim 8, further comprising:
a first light-transmitting material layer disposed in the transmissive area and located between the first substrate and the second supporting layer.

11. The electronic device of claim 1, further comprising:
a second substrate arranged opposite to the first substrate, wherein the light-emitting units and the first optical units are disposed between the first substrate and the second substrate.

12. The electronic device of claim 11, further comprising:
an adhesive layer disposed between the light-emitting units and the first optical units.

13. The electronic device of claim 1, further comprising:
a third substrate disposed at one side of the first substrate away from the light-emitting units;
a plurality of second optical units disposed between the third substrate and the first substrate, respectively, wherein the second optical units are disposed in the display areas, respectively; and
a plurality of second color filter units disposed between the third substrate and the second optical units, respectively, wherein the second color filter units are disposed in the display areas, respectively.

14. The electronic device of claim 13, wherein each of the second optical units comprises a third bank layer and a second light conversion element, and the third bank layer comprises a fourth opening for accommodating the second light conversion element.

15. The electronic device of claim 13, wherein each of the second color filter units comprises a second light-shielding layer and a second color filter element, and the second light-shielding layer comprises a fifth opening for accommodating the second color filter element.

16. The electronic device of claim 13, further comprising:
a fifth encapsulating layer disposed at one side of the first substrate away from the light-emitting units and located between the first substrate and the second optical units; and
a sixth encapsulating layer disposed under the second optical units;
wherein, the fifth encapsulating layer contacts the sixth encapsulating layer in the transmissive area, so that the second optical units are enclosed in a plurality of spaces formed by the fifth encapsulating layer and the sixth encapsulating layer.

17. The electronic device of claim 16, further comprising:
an adhesive layer disposed between the fifth encapsulating layer and the first substrate.

18. The electronic device of claim 16, further comprising:
a seventh encapsulating layer disposed under the second color filter units, wherein the sixth encapsulating layer contacts the seventh encapsulating layer in the transmissive area, so that the second color filter units are enclosed in a plurality of spaces formed by the sixth encapsulating layer and the seventh encapsulating layer.

19. The electronic device of claim 18, further comprising:
a second light-transmitting material layer disposed in the transmissive area and located between the first substrate and the fifth encapsulating layer.

20. The electronic device of claim 18, further comprising:
a second light-transmitting material layer disposed in the transmissive area and located between the first substrate and the second substrate.
